(19) United States
(12) Patent Application Publication
(10) Pub. No.: US 2017/0243634 A1
(43) Pub. Date: Aug. 24, 2017

(54) SEMICONDUCTOR MEMORY DEVICE INCLUDING SRAM CELLS

(71) Applicant: KABUSHIKI KAISHA TOSHIBA, Tokyo (JP)

(72) Inventor: Koji KOHARA, Yokohama Kanagawa (JP)

(21) Appl. No.: 15/252,043

(22) Filed: Aug. 30, 2016

(30) Foreign Application Priority Data
Feb. 19, 2016 (JP) 2016-030283

(51) Int. Cl. G11C 11/419; G11C 11/418

(52) U.S. Cl. CPC G11C 11/419; G11C 11/418

(57) ABSTRACT

A semiconductor memory device includes a plurality of static random access memory (SRAM) cells connected to a bit line pair comprising a first bit line and a second bit line. An equalizer circuit controls a connection between the first bit line and the second bit line. A timing control circuit controls the equalizer circuit such that the equalizer circuit disconnects the first bit line from the second bit line during a first mode and connects the first bit line to the second bit line during a second mode. The first mode permits data to be read from or written to the SRAM cells, and the second mode is a retention mode during which data is not read from or written to SRAM cells.

### CROSS-REFERENCE TO RELATED APPLICATION

This application is based upon and claims the benefit of priority from Japanese Patent Application No. 2016-030283, filed Feb. 19, 2016, the entire contents of which are incorporated herein by reference.

### FIELD

Embodiments described herein relate generally to a semiconductor memory device.

### BACKGROUND

An SRAM (Static Random Access Memory) can read and write data at a higher speed as compared to DRAM (Dynamic Random Access Memory) and NAND flash memory, and there is generally no need to perform a refresh operation as with DRAM. Therefore, the SRAM is often used as a cache memory of a central processing unit (CPU).

In a typical SRAM, a power-supply voltage can be lowered to reduce power consumption when in a retention mode in which only data retention is being performed (that is, no read/write operations are being conducted). A bit line pair is in a nominally floating state during this retention mode. However, in cases where a plurality of SRAM cells are connected to the bit line pair, the potential of the bit line pair may be changed under the influence of retained data of SRAM cells. More specifically, a bit line BL of the bit line pair can become a low potential (hereinafter, also referred to as L potential), and a bit line /BL easily becomes a high potential (hereinafter, also referred to as H potential) when the number of SRAM cells storing low data (hereinafter, also referred to as L data) among the plurality of SRAM cells is larger than the number of SRAM cells storing high data (hereinafter, also referred to as H data). Therefore, the retained data in the SRAM cell(s) storing the H data may be affected when the potential of the bit line BL is inverted.

### DESCRIPTION OF THE DRAWINGS

FIG. 1 is a block diagram schematically illustrating a configuration of a semiconductor memory device according to a first embodiment.

FIG. 2 is a circuit diagram of aspects of the semiconductor memory device the first embodiment.

FIG. 3 is a circuit diagram according to a modification of an equalizer circuit.

FIG. 4 is a circuit diagram illustrating a circuit configuration of a timing control circuit.

FIG. 5 is a timing chart of the semiconductor memory device according to the first embodiment.

FIG. 6 is a timing chart of the semiconductor memory device according to a comparative example having no equalizer circuit.

FIG. 7 is a diagram illustrating a situation that logic values of retained data of a plurality of SRAM cells are changed when a power-supply potential is changed.

FIG. 8 is a diagram illustrating a minimum power-supply potential at which the logic value of the retained data is changed.

FIG. 9 is a block diagram schematically illustrating a configuration of a semiconductor memory device according to a second embodiment.

FIG. 10 is a circuit diagram illustrating an internal configuration of a timing control circuit.

FIG. 11 is a timing chart of the semiconductor memory device according to the second embodiment.

FIG. 12 is a circuit diagram of aspects of a semiconductor memory device according to a third embodiment.

### DETAILED DESCRIPTION

In general, according to one embodiment, a semiconductor memory device includes a plurality of static random access memory (SRAM) cells connected to a bit line pair. The bit line pair comprises a first bit line and a second bit line. An equalizer circuit is configured to control an electrical connection between the first bit line and the second bit line. A timing control circuit is configured to control the equalizer circuit such that the equalizer circuit electrically disconnects the first bit line from the second bit line during a first operating mode and electrically connects the first bit line to the second bit line during a second operating mode. The first operating mode permits data to be read from or written to the plurality of SRAM cells, and the second operating mode being a retention mode during which data is not read from or written to plurality of SRAM cells.

Hereinafter, example embodiments of the present disclosure will be described with reference to the drawings.

### First Embodiment

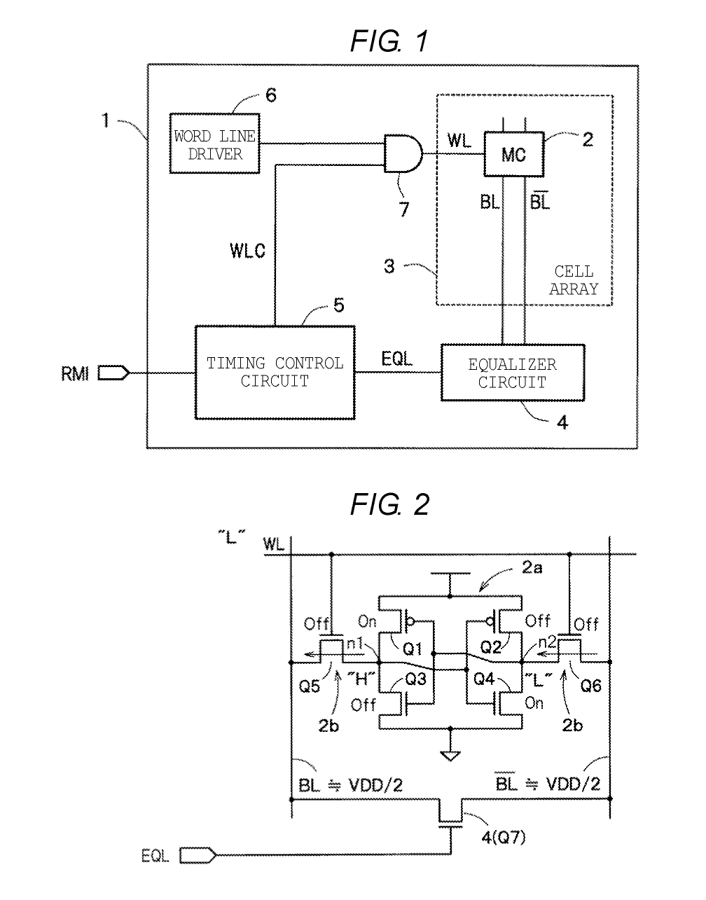

FIG. 1 is a block diagram schematically illustrating a configuration of a semiconductor memory device 1 according to a first embodiment. FIG. 2 is a circuit diagram of aspects of the semiconductor memory device 1 depicted in FIG. 1. The semiconductor memory device 1 according to this first embodiment is an SRAM. FIG. 2 illustrates a circuit configuration of one SRAM cell in the SRAM.

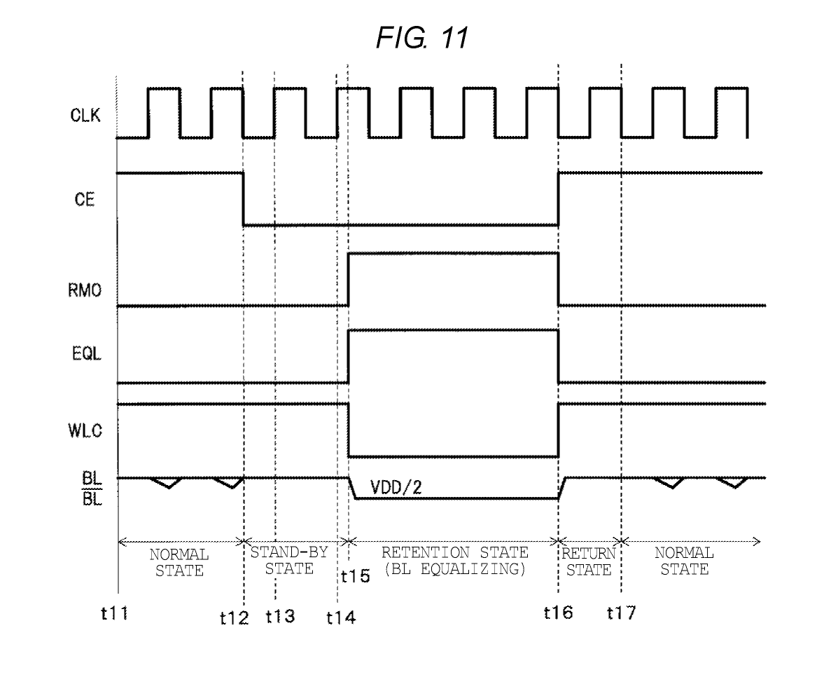

As illustrated in FIG. 11, the semiconductor memory device 1 according to this first embodiment is provided with a cell array 3 including the plurality of SRAM cells (MC) 2 connected to a bit line pair (BL & /BL), an equalizer circuit 4, and a timing control circuit 5. Each SRAM cell 2 has a first mode in which data can be read and written and a second mode in which the data is simply retained at a power-supply voltage lower than that of the first mode. The first mode is also called a normal mode, and the second mode is also called a retention mode.

The equalizer circuit 4 functions to short-circuit (electrically connect) the bit line pair BL, /BL to each other when the plurality of SRAM cells 2 are in the second mode. The timing control circuit 5 controls timing at which the equalizer circuit 4 short-circuits the bit line pair BL, /BL.

Additionally, the semiconductor memory device 1 is provided with a word line driver 6 which drives a word line WL, and an AND gate 7. In FIG. 1, only certain featured components are illustrated while other standard circuit components of an SRAM are omitted. In addition, while being omitted from FIG. 1, various signals, such as a clock signal CLK and a chip enable signal CE, are input or output with respect to the semiconductor memory device 1.

For an example, each SRAM cell 2 includes six MOS transistors Q1 to Q6 as illustrated in FIG. 2. Among these six MOS transistors, PMOS transistors Q1 and Q2 and NMOS transistors Q3 and Q4 form a data retention unit 2a, and NMOS transistors Q5 and Q6 form a data transfer unit 2b.

The transistors Q1 and Q3 in the data retention unit 2a are connected in series between a power voltage node and a ground voltage node. The transistors Q2 and Q4 are connected in series between the power voltage node and the ground voltage node. The gates of the transistors Q1 and Q3 are connected to the drains of the transistors Q2 and Q4. The gates of the transistors Q2 and Q4 are connected to the drains of the transistors Q1 and Q3.

The transistor Q5 in the data transfer unit 2b switches whether the bit line BL is connected to the drains of the transistors Q1 and Q3 and the gates of the transistors Q2 and Q4. The transistor Q6 switches whether the bit line /BL is connected to the drains of the transistors Q2 and Q4 and the gates of the transistors Q1 and Q3. The gates of the transistors Q5 and Q6 are connected to the word line WL.

In the second mode, the word line WL is a low potential (hereinafter, referred to as L logic), and the transistors Q5 and Q6 are turned off. On the other hand, the transistors Q1 to Q4 are connected in a cross manner, and retains data values even when the transistors Q5 and Q6 are turned off.

The equalizer circuit 4 includes an NMOS transistor Q7 which switches whether the bit line pair BL, /BL is short-circuited as illustrated in FIG. 2. An output signal EQL of the timing control circuit 5 is input to the gate of the transistor Q7. The equalizer circuit 4 turns on the transistor Q7 in the second mode to short-circuit the bit line pair BL, /BL. Therefore, the bit line pair BL, /BL becomes an intermediate potential (e.g., about VDD/2) between a power-supply potential VDD and a ground potential 0 V.

FIG. 2 illustrates an example in which the SRAM cell 2 retains data “1”. In this case, the drains of the transistors Q1 and Q3 become an H potential (e.g., about VDD), and the drains of the transistors Q2 and Q4 become an L potential (e.g., about 0 V). Since the bit line pair BL, /BL becomes the intermediate potential when the bit line pair BL, /BL is short-circuited by the equalizer circuit 4, there is no=concern that a leakage current will flow between the drains and the sources of the transistors Q5 and Q6.

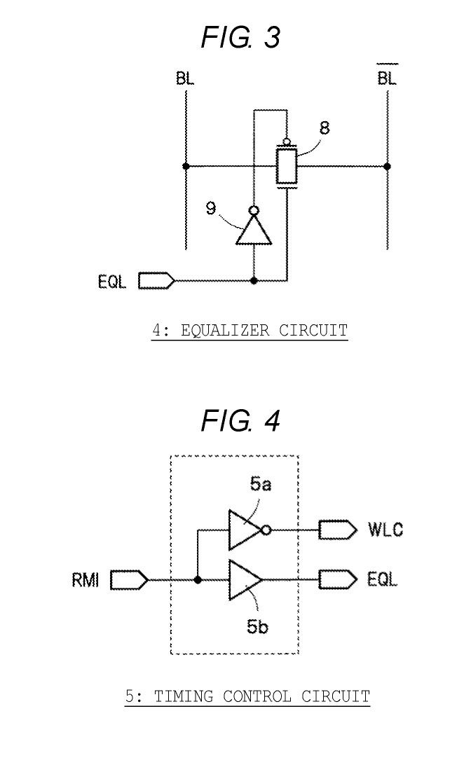

Furthermore, the equalizer circuit 4 is not limited to the specific configuration of having a single transistor Q7 as illustrated in FIG. 11. FIG. 3 is a circuit diagram according to a modification of the equalizer circuit 4. The equalizer circuit 4 of FIG. 3 includes a transfer gate 8 having two transistors different from each other in conductivity type and an inverter 9. The two transistors in the transfer gate 8 are turned on when the output signal EQL of the timing control circuit 5 becomes H logic, and turned off when the output signal EQL becomes L logic.

FIG. 4 is a circuit diagram illustrating an exemplary circuit configuration of the timing control circuit 5. The timing control circuit 5 of FIG. 4 includes an inverter 5a which inversely outputs a logic value of an external control signal RMI supplied from the outside of the semiconductor memory device 1, and a buffer 5b which outputs the logic value (the non-inverted value) of the external control signal RMI.

The external control signal RMI is supplied from a CPU (not illustrated) for example. The external control signal RMI is a signal to instruct the equalizer circuit 4 to short-circuit the bit line pair BL, /BL. For example, the external control signal RMI becomes the H logic when the bit line pair BL, /BL is to be short-circuited, and becomes the L logic in the first mode (the normal mode). The external control signal RMI can be used to set the power-supply potential to be low (L logic) after a certain time period elapses after a change to H logic. In addition, the external control signal RMI is necessarily set to the L logic after the power-supply potential returns to a normal potential.

An output signal WLC of the inverter 5a is input to the AND gate 7 illustrated in FIG. 1. The AND gate 7 generates an AND signal WL between an output signal of the word line driver 6 and the output signal WLC of the inverter 5a to drive the word line WL. In other words, the AND gate 7 outputs the signal WL to drive the corresponding word line WL when a signal is output from the word line driver 6 to drive a specific word line WL and the external control signal RMI is the L logic. When the external control signal RMI becomes the L logic the bit line pair BL, /BL is not short-circuited, and this corresponds to the first mode. On the other hand, when the bit line pair BL, /BL is short-circuited, the output of the AND gate 7 becomes the L logic, and the word line WL is not driven.

The output signal EQL of the buffer 5b is input to the gate of the NMOS transistor Q7 in the equalizer circuit 4. When the external control signal RMI is the H logic, the output signal EQL of the buffer 5b also becomes the H logic, the NMOS transistor Q7 is turned on to short-circuit the bit line pair BL, /BL, and the bit line pair BL, /BL becomes a common potential.

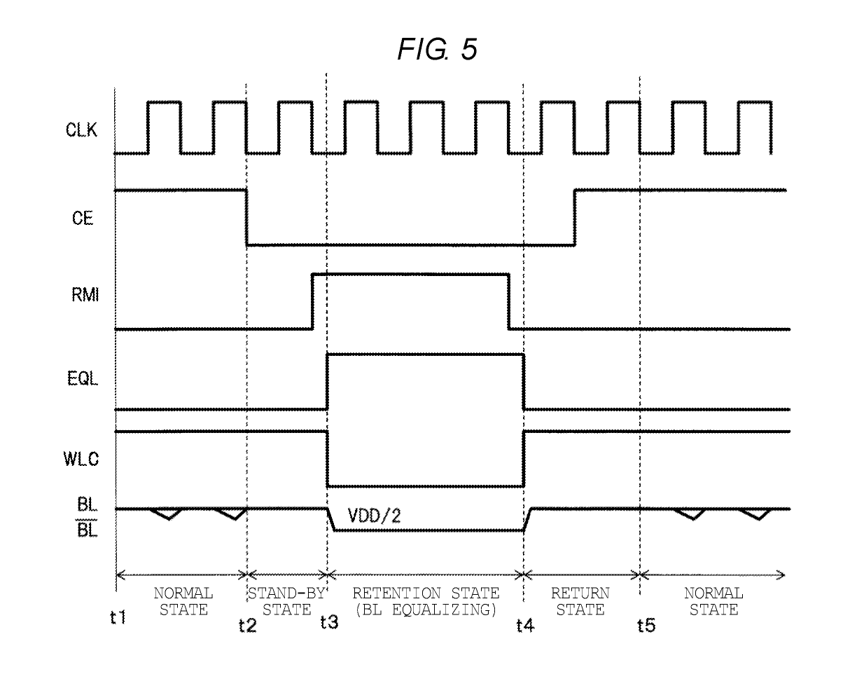

FIG. 5 is a timing chart of the semiconductor memory device 1 according to the first embodiment. The chip enable signal CE supplied from the outside to the semiconductor memory device 1 becomes the H logic in the first mode, and becomes the L logic in other cases. The external control signal RMI becomes the H logic after a predetermined time period after the chip enable signal CE becomes the L logic, and returns to the L logic at a predetermined time period from when the chip enable signal CE is changed from the L logic to the H logic.

When the external control signal RMI becomes the H logic, the output signal EQL of the buffer 5b becomes the H logic. In FIG. 5, a period from time t2 when the chip enable signal CE becomes the L logic to time t3 when the output signal EQL of the buffer 5b becomes the H logic is called a stand-by state.

When the output signal EQL becomes the H logic, the equalizer circuit 4 short-circuits the bit line pair BL, /BL. Therefore, the bit line pair BL, /BL becomes the intermediate potential VDD/2 between the power-supply potential (for example, VDD) and the ground potential (for example, 0 V) of the semiconductor memory device 1.

Thereafter, when the external control signal RMI becomes the L logic, the output signal EQL becomes the L logic. A period (time from t3 to t4) when the output signal EQL is the H logic is the second mode. Thereafter, the chip enable signal CE returns to the H logic. In FIG. 5, a period (time from t4 to t5) from time t4 until the chip enable signal CE returns to the H logic to let down the clock signal CLK is called a return state. After time t5, the memory device returns to the first mode.

In this way, in this first embodiment, since the bit line pair BL, /BL is set to the intermediate potential in the second mode, there occurs no error in which a logic value of retained data of the SRAM cell 2 is inverted by the influence of the potential of the bit line pair BL, /BL.

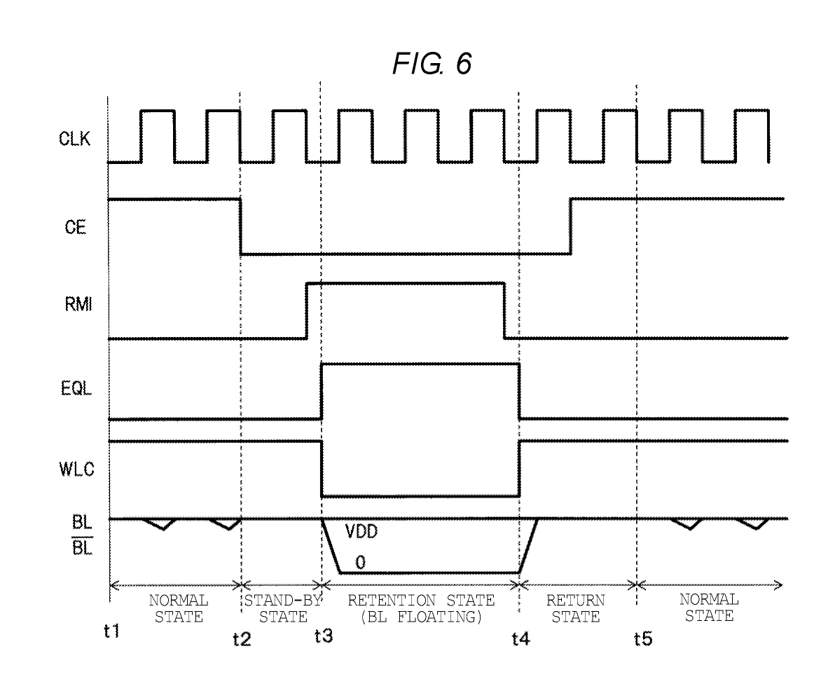

FIG. 6 is a timing chart according to a comparative example that has no equalizer circuit 4. When there is no equalizer circuit 4, the potential of the bit line pair BL, /BL may be affected by the retained data of the plurality of SRAM cells 2 which are connected to the bit line pair BL, /BL. For example, in a case where a majority of SRAM cells 2 among the plurality of SRAM cells 2 connected to the bit line pair BL, /BL retain the L logic data, the bit line BL can approach the L potential (about 0 V) and the bit line /BL can approach the H potential (about VDD) as illustrated in FIG. 6. When there are some of the SRAM cells 2 that retain the H logic data, leakage current can flow between the drains and the sources of the transistors Q5 and Q6 in the SRAM cell illustrated in FIG. 2. Therefore, the logic of the retained data may be inverted in error. However, in the case of this first embodiment, even when the majority of SRAM cells 2 among the plurality of SRAM cells 2 connected to the bit line pair BL, /BL retain the L logic data, the bit line pair is set to the intermediate potential (about VDD/2) by the equalizer circuit 4. Therefore, there is no concern that the data of the SRAM cells 2 retaining the H logic data will be inverted.

In the semiconductor memory device 1 according to this first embodiment, the power-supply potential can be lowered in the second mode as compared to the first mode in order to achieve lower power consumption. When the power-supply potential is lowered, the potential of the bit line pair BL, /BL may also be lowered. Even in this first embodiment, the logic value of the retained data of the SRAM cell 2 may be inverted in such a scenario. In addition, the logic value of the retained data may be inverted by a variation in characteristics of the respective SRAM cells 2, or changes in the power-supply potential.

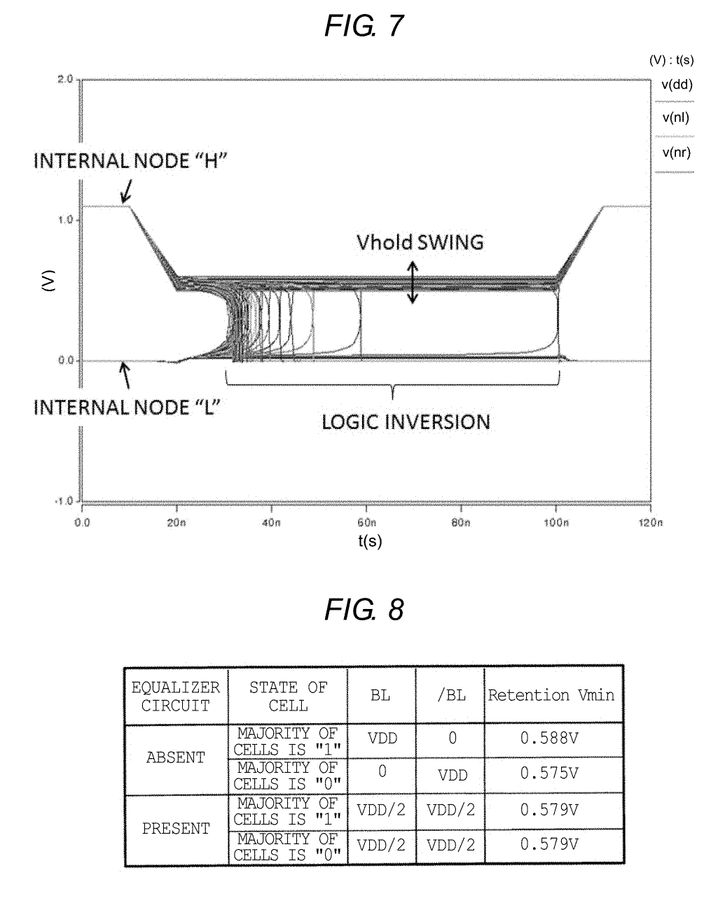

FIG. 7 is a diagram illustrating a situation that the logic values of the retained data of the SRAM cells 2 when the power-supply potential is changed. The horizontal axis of FIG. 7 represents time, and the vertical axis represents the potential at internal nodes n1 and n2 in the SRAM cell 2. The plurality of lines depicted in the figure represent states of different power-supply potentials. As illustrated in FIG. 7, the logic value of the retained data can be inverted by setting the power-supply potential to be too low. In addition, it can be seen that the timing when the logic value of the data retained in the SRAM cell 2 is inverted becomes earlier as the power-supply potential is lowered.

FIG. 8 is a diagram illustrating a minimum power-supply potential at which the logic value of the retained data is not changed. FIG. 8 illustrates a case where a certain SRAM cell 2 retains the L logic data among the plurality of SRAM cells 2 connected to the bit line pair BL, /BL. In FIG. 8, when the equalizer circuit 4 is provided, the minimum power-supply potential at which the retained data of the certain SRAM cell 2 will not be changed is 0.579 V even when the majority of SRAM cells 2 are “1” or “O”. On the contrary, when the equalizer circuit 4 is not provided, the minimum power-supply potential at which the retained data of the certain SRAM cell 2 is not changed is 0.588 V when the majority of the other SRAM cells 2 are “1” valued retained data. Therefore, an improvement of 0.588V−0.579V=0.009V (9 mV) is obtained. It is considered that this improvement is obtained because the equalizer circuit 4 is provided and the bit line pair BL, /BL can be set to the intermediate potential.

Furthermore, in a case where the majority of cells are “0”, the retained data of the SRAM cell 2 will be unlikely to be inverted. Therefore, the inversion in this case does not occur by a lowering of the power-supply potential to 0.575 V.

In this way, in the first embodiment, the bit line pair BL, /BL is short-circuited by the equalizer circuit 4 in the second mode where the data of the SRAM cell 2 is retained in a state of a low power-supply voltage. Therefore, the bit line pair BL, /BL can be set to the intermediate potential. Accordingly, even in a case where the majority of SRAM cells 2 among the plurality of SRAM cells 2 connected to the bit line pair BL, /BL retain specific data, there occurs no error in which the retained data of a cell is affected by the influence of the retained data of the other cells on the bit line pair BL, /BL and thus the retained data of the SRAM cells 2 will not be inverted. Therefore, it is possible to improve a data retention property of the SRAM cell while in the second mode.

### Second Embodiment

In the first embodiment, the timing of the second mode was controlled according to the external control signal RMI supplied from outside of the semiconductor memory device 1. In a second embodiment, the timing of the second mode is determined inside the semiconductor memory device 1 itself.

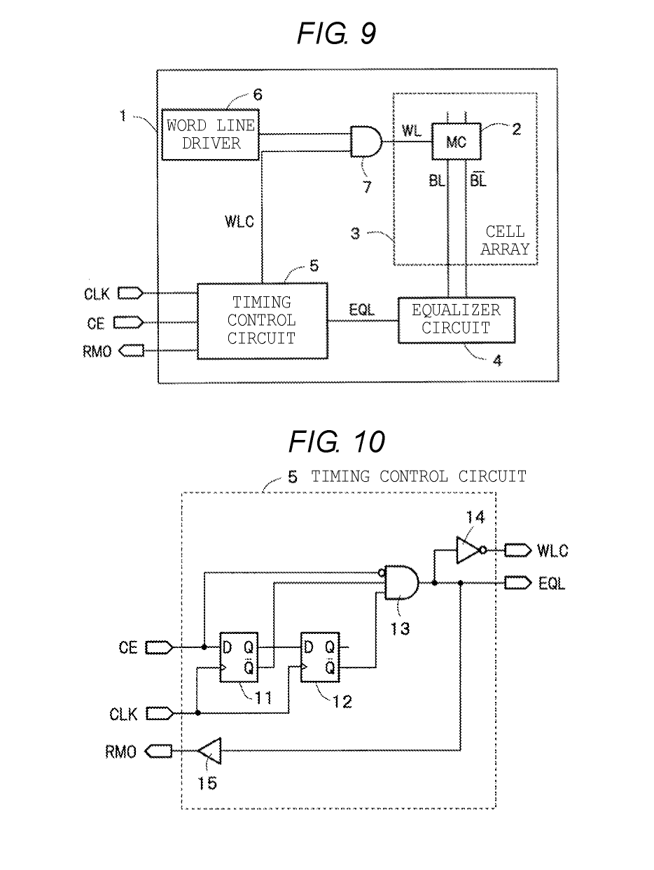

FIG. 9 is a block diagram schematically illustrating a configuration of the semiconductor memory device 1 according to the second embodiment. A signal to be input or output with respect to the timing control circuit 5 of FIG. 9 is different from that of the timing control circuit 5 of FIG. 1. More specifically, the clock signal CLK and the chip enable signal CE are input to the timing control circuit 5 of FIG. 9. In addition, a signal RMO indicating a period of the second mode is output from the timing control circuit 5 of FIG. 9. The signal RMO is supplied to a CPU (not illustrated) for example. The CPU determines whether there is required a return time after the signal CE has been set to the H logic by the state of the signal RMO until writing or reading is performed. In addition, the signal RMO can also be used to set the power-supply potential to be low by being input to an external power-supply potential generating circuit (not specifically illustrated).

The semiconductor memory device 1 according to the second embodiment is different from the first embodiment in the internal configuration of the timing control circuit 5, but the other configurations are substantially common with those of the first embodiment. The circuit configuration of the SRAM cell 2 in the second embodiment is also common to that depicted in FIG. 2 for the first embodiment.

FIG. 10 is a circuit diagram illustrating the internal configuration of the timing control circuit 5 of FIG. 9. The timing control circuit 5 of FIG. 10 includes two D type flip-flops (hereinafter, referred to as DF/F) 11 and 12 which are connected in series, a logical operation circuit 13, an inverter 14, and a buffer 15.

The DF/F 11 and DF/F 12 synchronize the chip enable signal CE to the rising edge of the clock signal CLK. The logical operation circuit 13 outputs the H logic signal EQL when the chip enable signal CE is the L logic, the output /Q of the DF/F 11 at the previous stage is the H logic, and the output /Q of the DF/F 12 at the later stage is the H logic. The inverter 14 outputs a signal WLC which is obtained by inverting the signal EQL. The buffer 15 outputs a signal of the same logic value as that of the signal EQL.

FIG. 11 is a timing chart of the semiconductor memory device 1 according to the second embodiment. The time from t11 to t12 corresponds to the first mode. When the clock signal CLK rises at time t13 after the chip enable signal CE becomes the L logic at time t12, the output Q of the DF/F 11 becomes the L logic. Thereafter, when the clock signal CLK rises again at time t14, the output Q of the DF/F 12 also becomes the L logic. Therefore, the output signal EQL and the signal RMO of the logical operation circuit 13 become the H logic at time t15, and the signal WLC becomes the L logic. Accordingly, the equalizer circuit 4 short-circuits the bit line pair BL, /BL, and the bit line pair BL, /BL becomes the intermediate potential VDD/2.

Thereafter, when the chip enable signal CE becomes the H logic at time t16, the output signal EQL and the signal RMO of the logical operation circuit 13 are inverted to the L logic, and the signal WLC is inverted to the H logic. Therefore, the equalizer circuit 4 stops short circuiting the bit line pair BL, /BL. In this way, the time period from t15 to t16 corresponds to the second mode.

In this way, in the second embodiment, the chip enable signal CE supplied from the outside can be synchronized with the clock signal CLK to set the period of the second mode. Accordingly, there is no need to specifically designate the period of the second mode from the outside. In addition, even in the second embodiment, the bit line pair BL, /BL can be set to the intermediate potential in the second mode similarly to the first embodiment. It is thus possible to prevent an unintended inversion of the retention data of the SRAM cell 2.

### Third Embodiment

In a third embodiment, a test can be performed on whether the data written (presently retained) in the SRAM cell 2 will be inverted by the potential of the bit line pair BL, /BL. As described above, in a case where the majority of SRAM cells 2 among the plurality of SRAM cells 2 connected to the bit line pair BL, /BL store data “0”, the bit line BL easily becomes the L potential. Under such influence (bit line BL=L potential), the retained data of those particular SRAM cells 2 storing data “1” may be easily inverted (that is become “0” value data in error). Therefore, a test of whether such an error will occur is performed in the third embodiment. More specifically, the potential of the bit line pair BL, /BL is inverted, and it is determined whether the stored data in a SRAM cell 2 is inverted by the inversion in bit line pair BL, /BL potential. In this third embodiment, even though it is not confirmed in advance which potential of the bit line pair BL, /BL will cause the retained data of the SRAM cell 2 to be inverted, the SRAM cell 2 can be determined as normal by confirming that the retained data of the SRAM cell 2 is not changed when the potential to be applied to the bit line pair BL, /BL is inverted.

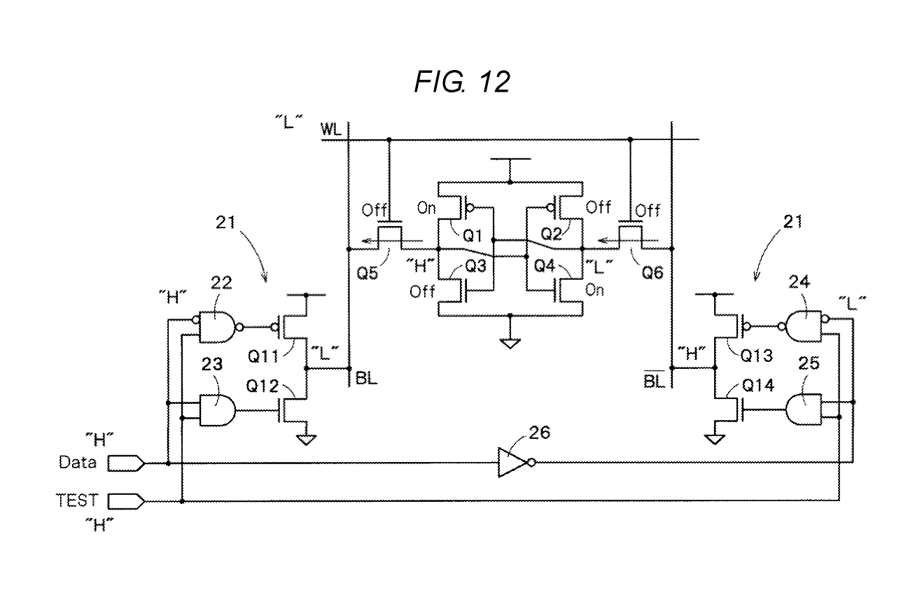

FIG. 12 is a circuit diagram of aspects of the semiconductor memory device 1 according to the third embodiment. The semiconductor memory device 1 of FIG. 12 includes the SRAM cell 2 and a test control circuit 21. The SRAM cell 2 has substantially the same circuit configuration as that depicted in FIG. 2.

The test control circuit 21 performs a test about whether the retained data in the plurality of SRAM cells 2 is inverted when first complementary data of a first test value (e.g., L for bit line BL and H for bit line /BL) is supplied to the bit line pair BL, /BL while the plurality of SRAM cells 2 are in the second mode. Next, the test control circuit 21 performs a test about whether the retained data in the plurality of SRAM cells 2 is inverted when second complementary data that has a second test value (e.g., H for bit line BL and L for bit line /BL) inverse to the first complementary data is supplied to the bit line pair BL, /BL.

The test control circuit 21 includes a PMOS transistor Q11 and an NMOS transistor Q12 which are connected between the power voltage node and the ground voltage node, a first gate control circuit 22 which controls the gate voltage of the transistor Q11, a second gate control circuit 23 which controls the gate voltage of the transistor Q12, a PMOS transistor Q13 and an NMOS transistor Q14 which are connected between the power voltage node and the ground voltage node, a third gate control circuit 24 which controls the gate voltage of the transistor Q13, a fourth gate control circuit 25 which controls the gate voltage of the transistor Q14, and an inverter 26.

The drain of the PMOS transistor Q11 and the drain of the NMOS transistor Q12 both are connected to the bit line BL. The drain of the PMOS transistor Q13 and the drain of the NMOS transistor Q14 both are connected to the bit line /BL.

The first gate control circuit 22 inputs an NAND signal between an inversion logic of test data Data and a test mode signal TEST to the gate of the transistor Q11. The second gate control circuit 23 inputs an AND signal between the test data Data and the test mode signal TEST to the transistor Q12. The third gate control circuit 24 inputs an NAND signal between the test data Data and the test mode signal TEST to the gate of the transistor Q13. The fourth gate control circuit 25 inputs an AND signal between an inversion logic of the test data Data and the test mode signal TEST to the gate of the transistor Q13.

The semiconductor memory device 1 of FIG. 12 can correctly perform a test on the SRAM cell 2 even when there is no confirmation in advance what if any potential of the bit line pair BL, /BL may cause (or allow) the retained data of the SRAM cell 2 to be inverted. In this third embodiment, for example, it is first that the retained data of the SRAM cell 2 is not inverted when the L potential is applied to the bit line BL and the H potential is applied to the bit line /BL. This may be referred to as applying first complementary data to the bit line pair BL, /BL. Next, it is confirmed that the retained data of the SRAM cell 2 is not inverted when the H potential is applied to the bit line BL and the L potential is applied to the bit line /BL. This may be referred to as applying second complementary data to the bit line pair BL, /BL. Therefore, it is possible to perform a test about whether the retained data of the SRAM cell 2 will be inverted even in cases of in which the retained data of the majority of SRAM cells 2 in the plurality of SRAM cells 2 connected to the particular bit line pair BL, /BL is “0” or “1”.

FIG. 12 illustrates an example in which the H logic data is stored in the SRAM cell 2. In this case, when the bit line BL is set to the L potential and the bit line /BL is set to the H potential, leakage current flows from the SRAM cell 2 toward the bit line BL. Furthermore, the leakage current flows from the bit line /BL toward the SRAM cell 2. According to the third embodiment, when the H logic data is supplied as the test data signal Data while the test mode signal TEST is set to be “High”, it is possible to set the bit line BL to the L potential and the bit line /BL to the H potential. In this state, the SRAM cell 2 is considered as normal if the retained data of the SRAM cell 2 is not inverted by the application of the H potential to the bit line BL and the L potential to the bit line /BL.

In this way, according to the third embodiment, when a test is performed as to whether the retained data of the SRAM cell 2 is inverted when the potential of the bit line pair BL, /BL is inverted, and even when a majority of SRAM cells 2 among the plurality of SRAM cells 2 connected to the bit line pair BL, /BL retain the same data value, it is possible to verify in advance whether the retained data of the other SRAM cells 2 will be inverted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device, comprising:
a plurality of static random access memory (SRAM) cells connected to a bit line pair comprising a first bit line and a second bit line;
an equalizer circuit configured to control an electrical connection between the first bit line and the second bit line; and
a timing control circuit configured to control the equalizer circuit such that the equalizer circuit electrically disconnects the first bit line from the second bit line during a first operating mode and electrically connects the first bit line to the second bit line during a second operating mode, the first operating mode permitting data to be read from or written to the plurality of SRAM cells, and the second operating mode being a retention mode during which data is not read from or written to the plurality of SRAM cells and the bit line pair is in a floating electrical state.

2. The semiconductor memory device according to claim 1, wherein the equalizer circuit sets the bit line pair to an intermediate potential between a power-supply potential and a ground potential during the second mode.

3. The semiconductor memory device according to claim 1, wherein the timing control circuit controls the equalizer circuit on the basis of an external control signal.

4. The semiconductor memory device according to claim 1, wherein the timing control circuit is configured to control the equalizer circuit to electrically connect the first and second bit lines after an elapse of a predetermined time period in the first operation mode during which the plurality of SRAM cells has not been accessed for reading or writing data.

5. The semiconductor memory device according to claim 1, wherein the equalizer circuit consists of a single transistor connected between the first and second bit lines.

6. The semiconductor memory device according to claim 1, wherein the equalizer circuit comprises a transistor having a source connected to the first bit line, a drain connected to the second bit line, and a gate connected to the timing control circuit.

7. The semiconductor memory device according to claim 1, wherein the equalizer circuit includes a transfer gate comprising two transistors that are different conductivity types.

8. The semiconductor memory device according to claim 1, wherein the timing control circuit controls the equalizer circuit on the basis of an external control signal and comprises a buffer connected to the equalizer circuit and configured to receive the external control signal.

9. The semiconductor memory device according to claim 1, wherein the timing control circuit comprises at least two D-type flip-flop circuits connected in series and a logical operation circuit having at least three inputs, at least two of which are respectively connected to an output of the at least two D-type flip-flop circuits, and a third input of the at least three inputs of the logical operation circuit is connected to a chip enable signal terminal, wherein the logical operation circuit is configured to output a signal at a first logic level when a chip enable signal that is received at the chip enable signal terminal is a second logic level and the outputs of the at least two D-type flip-flop connected to the logical operation circuit supply signals are at the first logic level.

10. The semiconductor memory device according to claim 1, further comprising:
a test control circuit configured to perform:
a first test as to whether data presently retained in the plurality of SRAM cells inverts when a first potential is applied to the first bit line and a second potential opposite the first potential is applied to the second bit line, and
a second test as to whether data presently retained in the plurality of SRAM cells inverts when the second potential is applied to the first bit line and the first potential is applied to second bit line.

11. The semiconductor memory device according to claim 10, wherein
the test control circuit is configured to perform the first and second test prior to entering the second operating mode.

12. The semiconductor memory device according to claim 10, wherein the test control circuit comprises:
a first transistor of a first conductivity type;
a second transistor of a second conductivity type connected in series with the first transistor between a power supply potential and a ground potential, a first node between the first and second transistors being connected to the first bit line;
a first NAND circuit having an output connected to a gate of the first transistor and inputs connected to a test signal terminal and a data signal terminal;
a first AND circuit having an output connected to a gate of the second transistor and inputs connected to the test signal terminal and the data signal terminal;
a third transistor of the first conductivity type;
a fourth transistor of the second conductivity type connected in series with the third transistor between the power supply potential and the ground potential, a second node between the third and fourth transistors being connected to the second bit line;
a second NAND circuit having an output connected to a gate of the third transistor, a first input connected to the data signal terminal via an inverter that inverts a data signal supplied to the data signal terminal, and a second input connected to the test signal terminal; and
a second AND circuit having an output connected to a gate of the fourth transistor and a first input connected to the data signal terminal via the inverter, and a second input connected to the test signal terminal.

13. A semiconductor memory device, comprising:
a complementary bit line pair comprising a first bit line and a second bit line;
a plurality of static random access memory (SRAM) cells connected to the complementary bit line pair;
an equalizer circuit connected between the complementary bit line pair in parallel with the plurality of SRAM cells;
a timing control circuit configured to receive an external control signal and to provide an equalizer control signal to the equalizer circuit, wherein
the equalizer circuit electrically disconnects the first and second bit lines from each other when the equalizer control signal is at a first level and electrically connects the first and second bit lines to each other when the equalizer control signal is at a second level, and
the timing control circuit is configured to output the equalizer control signal at the first level when the plurality of SRAM cells is being set to a normal operating mode and to output the equalizer control signal at the second level when the plurality of SRAM cells is being set to a low-power level retention mode during which the complementary bit line pair is in a floating electrical state.

14. The semiconductor memory device according to claim 13, wherein an external control signal supplied to the timing control circuit controls whether the plurality of SRAM cells is set to the normal operating mode or the low-power level retention mode.

15. The semiconductor memory device according to claim 13, wherein the timing control circuit is configured to output the equalizer control signal at the second level after an elapse of a predetermined time period during which the plurality of SRAM cells has been in the normal operating mode without having been accessed for reading or writing data.

16. The semiconductor memory device according to claim 13, wherein the equalizer circuit consists of a single transistor connected between the first and second bit lines and the equalizer control signal is supplied to a gate of the single transistor.

17. The semiconductor memory device according to claim 13, wherein the equalizer circuit includes a transfer gate comprising two transistors that are different conductivity types.

18. A semiconductor memory device, comprising:
a plurality of static random access memory (SRAM) cells connected to a bit line pair comprising a first bit line and a second bit line, the plurality of SRAM cells being operable in a first mode in which data can be read from or written to the plurality and during a second mode in which data is retained while a power-supply voltage lower than in the first mode is supplied to the plurality; and
a test control circuit configured to perform, during the second mode, a first test as to whether data presently retained in the plurality of SRAM cells inverts when a first potential is applied to the first bit line and a second potential opposite the first potential is applied to the second bit line, and a second test as to whether data presently retained in the plurality of SRAM cells inverts when the second potential is applied to the first bit line and the first potential is applied to second bit line, wherein the test control circuit comprises:
a first transistor of a first conductivity type;
a second transistor of a second conductivity type connected in series with the first transistor between a power supply potential and a ground potential, a first node between the first and second transistors being connected to the first bit line;
a first NAND circuit having an output connected to a gate of the first transistor and inputs connected to a test signal terminal and a data signal terminal;
a first AND circuit having an output connected to a gate of the second transistor and inputs connected to the test signal terminal and the data signal terminal;
a third transistor of the first conductivity type;
a fourth transistor of the second conductivity type connected in series with the third transistor between the power supply potential and the ground potential, a second node between the third and fourth transistors being connected to the second bit line;
a second NAND circuit having an output connected to a gate of the third transistor, a first input connected to the data signal terminal via an inverter that inverts a data signal supplied to the data signal terminal, and a second input connected to the test signal terminal; and
a second AND circuit having an output connected to a gate of the fourth transistor and a first input connected to the data signal terminal via the inverter, and a second input connected to the test signal terminal.

19. (canceled)
